(19) United States
(12) Patent Application Publication
(10) Pub. No.: US 2019/0239390 A1
(43) Pub. Date: Aug. 1, 2019

(54) ENCLOSURE FOR LIQUID COOLING OF AN ELECTRONIC DEVICE

(71) Applicant: Mentor Graphics Corporation, Wilsonville, OR (US)

(72) Inventors: Terry Goode, Sunnyvale, CA (US); Spencer Saunders, Bedfordshire (GB)

(21) Appl. No.: 15/885,049

(22) Filed: Jan. 31, 2018

(51) Int. Cl. H05K 7/20; G06F 1/20

(52) U.S. Cl. CPC H05K 7/20281; G06F 2200/201; G06F 1/20; H05K 7/20272

(57) ABSTRACT

This application discloses a device that emits heat during operation, and an enclosure having walls forming a cavity to hold a first fluid. The walls also form a recess to retain a second fluid external from the cavity. The device can be disposed in the recess and at least partially submerged in the second fluid. The second fluid can absorb the heat emitted by the device and transfer the absorbed heat to the first fluid through the walls of the enclosure shared between the cavity and the recess. The enclosure can include an inlet port configured to allow the first fluid into the cavity and an outlet port configured to output the first fluid from the cavity. A flow of the first fluid through the cavity from the inlet port to the outlet port can dissipate the heat transferred from the device to the first fluid.

### TECHNICAL FIELD

This application is generally related to liquid cooling of devices and, more specifically, to an enclosure having an integrated condenser for liquid cooling of devices.

### BACKGROUND

As with most electronics and mechanical systems, during operation, the devices can emit heat as a by-product of the operations. The intensity of the heat can rise to the level where air cooling systems become impractical. Many electronic and mechanical systems utilize liquid cooling systems, for example, immersing the devices in a large sealed vat of electrically inert fluid, which can allow the heat from the electronics and mechanical systems to transfer to the inert fluid, which can flow outside the system and be cooled externally. While these types of liquid cooling systems can transfer heat away from the electronics and mechanical system, they utilize a large volume of expensive inert fluid.

### SUMMARY

This application discloses a device, such as an electronic or mechanical device, configured to emit heat during operation, and an enclosure having walls forming a cavity to hold a first fluid. The walls also form a recess to retain a second fluid external from the cavity. The electronic or mechanical device can be disposed in the recess and at least partially submerged in the second fluid. The second fluid can absorb the heat emitted by the at least partially submerged devices and transfer the absorbed heat to the first fluid through the thermally conductive walls of the enclosure shared between the cavity and the recess. The enclosure can include an inlet port configured to allow the first fluid into the cavity and an outlet port configured to output the first fluid from the cavity. A flow of the first fluid through the cavity from the inlet port to the outlet port can dissipate the heat transferred from the electronic device to the first fluid. Embodiments will be described in greater detail below.

### DESCRIPTION OF THE DRAWINGS

FIG. 1 illustrates an example of a sealed liquid cooling system.

FIGS. 2A-2C illustrate an example of a sealed liquid cooling system with integrated condenser.

FIGS. 3A-3C illustrate another example of a sealed liquid cooling system with integrated condenser.

### DETAILED DESCRIPTION

### Illustrative Sealed Liquid Cooling System

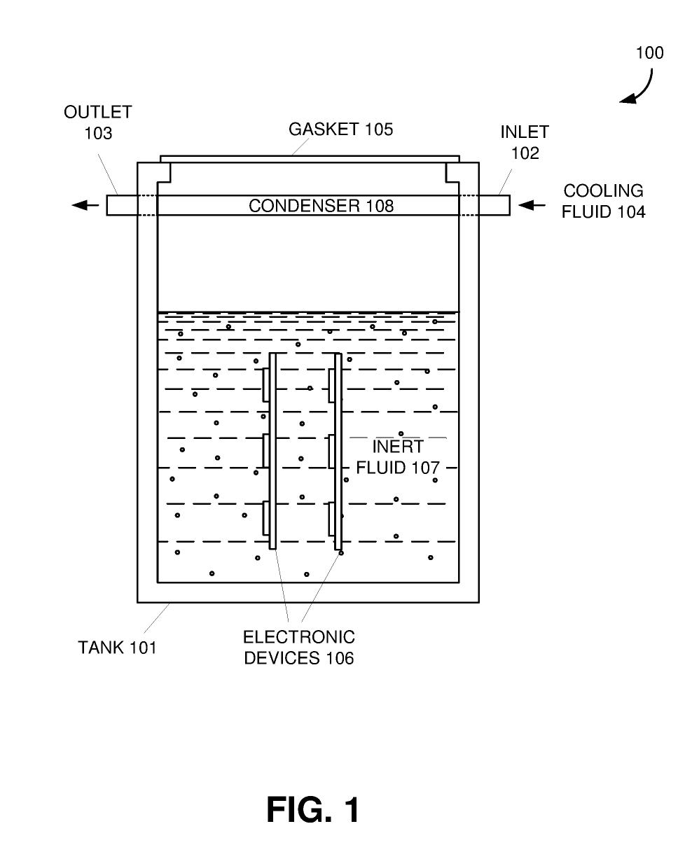

FIG. 1 illustrates an example of a sealed liquid cooling system 100 for electronic devices 106. Referring to FIG. 1, the sealed liquid cooling system 100 can include a tank 101 to hold a reservoir of an inert fluid 107. The inert fluid 107 can be an electrically inert fluid, such as Fluorinert® or the like, which can be an electrically insulating stable fluorocarbon-based fluid. The tank 101 can have an opening, for example, at the top, to allow the inert fluid 107 and the electronic devices 106 to be added to the tank 101. The sealed liquid cooling system 100 can include a gasket 105 to seal the opening in the tank 101.

The electronic devices 106, during operation, can generate heat, which can be transferred to the inert fluid 107 within the tank 101. Since the gasket 105 seals the tank 101, the more heat generated by the electronic devices 106, the higher the temperature of the inert fluid 107 and the remaining air in the tank 101 can become without additional heat dissipation.

The sealed liquid cooling system 100 also can include a condenser 108 located above the top-level of the inert fluid 107, for example, separating the inert fluid 107 from the condenser 108 with an air gap. The condenser 108 can have multiple ports, such as an inlet 102 and an outlet 103 for transport of a cooling fluid 104 through the condenser 108. The cooling fluid 104 may be water or other liquid capable of absorbing heat while passing through the condenser 108. The condenser 108 can be sealed, such that the cooling fluid 104 remains separated from the inert fluid 107.

The condenser 108 can receive the cooling fluid 104 via the inlet 102 and output the cooling fluid 104 via the outlet 103. As the cooling fluid 104 passes through the condenser 108 within the tank 101 sealed by the gasket 105, the cooling fluid 104 can absorb heat from within the tank 101, such as heat generated by operation of electronic devices 106. When the condenser 108 outputs the cooling fluid 104, the heat absorbed by the cooling fluid 104 from within the tank 101 has removed.

The sealed liquid cooling system 100 operates as a two phase cooling system. When the inert fluid 107 becomes warm enough to change phases, for example, boil and/or partially evaporate, the vaporized portion of the inert fluid 107 can rise to come in contact with the condenser 108, where the transfer of heat from the vaporized portion of the inert fluid 107 to the cooling fluid 104 in the condenser 108 can cause the inert fluid 107 to transition to a liquid state from a vaporized state and fall back into the reservoir of the inert fluid 107 in the tank 101.

Sealed Liquid Cooling System with Integrated Condenser

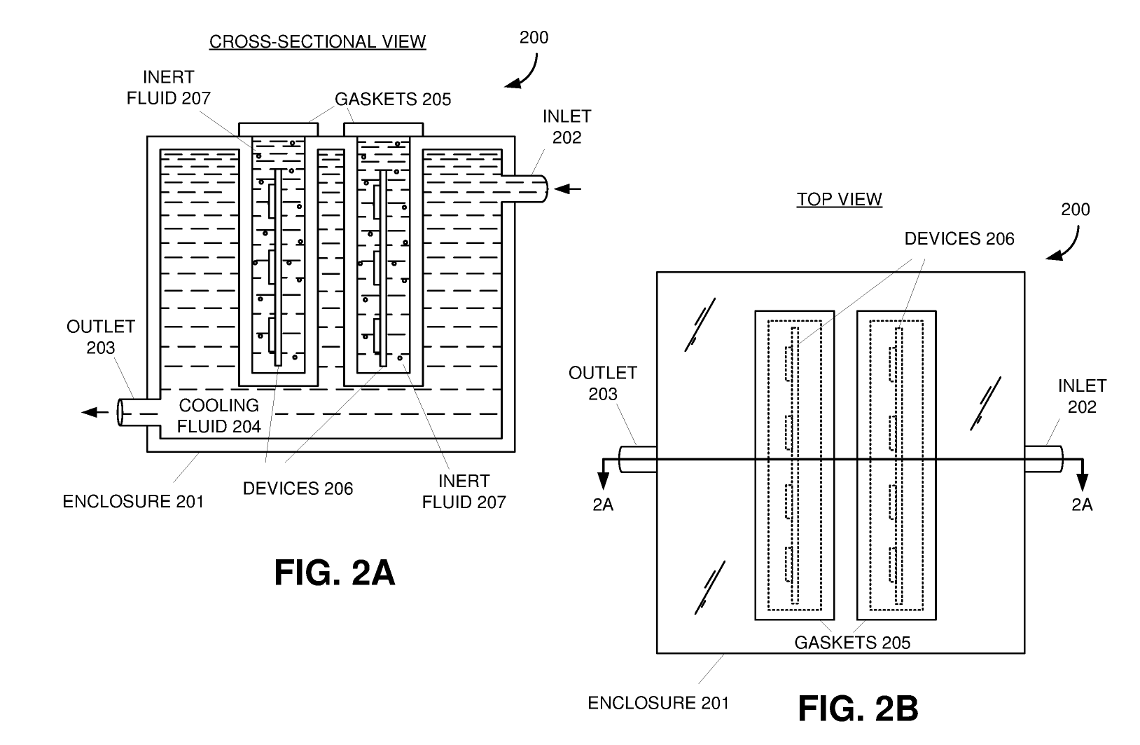

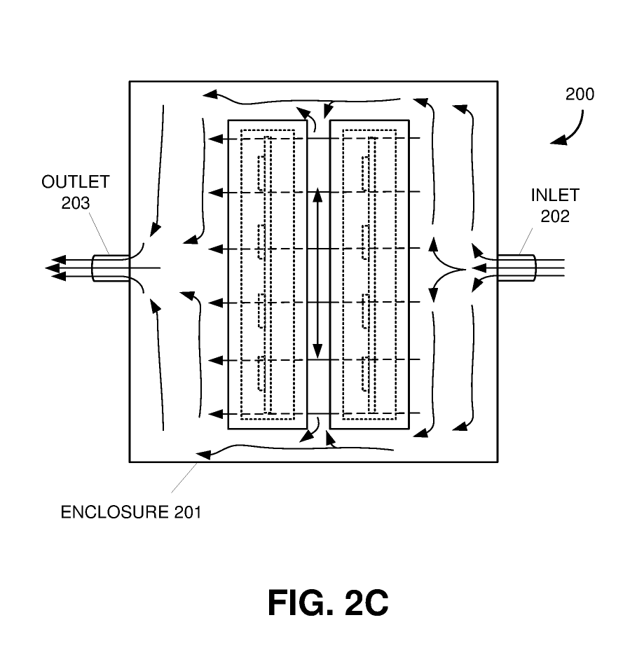

FIGS. 2A-2C illustrate an example of a sealed liquid cooling system 200 with integrated condenser. Referring to FIGS. 2A-2C, the sealed liquid cooling system 200 can include an enclosure 201 having multiple recesses to hold inert fluid 207 and devices 206 submerged or at least partially submerged in the inert fluid 207. The inert fluid 207 can be an electrically inert fluid, such as Fluorinert® or the like, which can be an electrically insulating stable fluorocarbon-based fluid. The devices 206 also may be electronic devices, such as integrated circuits, printed circuit boards, or the like, or the devices 206 may be mechanical devices, such as motors, industrial machinery, or the like. In some embodiments, the electronic devices may be a portion of an emulation system and/or a prototyping system having programmable logic devices mounted on printed circuit boards, for example, configured to implement functionality described in a logical design for an electronic system to be functionally verified.

The recesses in the enclosure 201 include corresponding openings, for example, allowing the addition and removal of the inert fluid 207 and/or the devices 206 from the recesses in the enclosure 201. The sealed liquid cooling system 200 can include gaskets 205 configured to detachably couple to the enclosure to seal or close the openings, for example, encapsulating the inert fluid 207 and the devices 206 submerged or at least partially submerged in the recesses of the enclosure 201. The devices 206, during operation, can generate heat, which can be transferred to or absorbed by the inert fluid 207 within the corresponding recesses of the enclosure 201. Since the gaskets 205 can seal the recesses in the enclosure 201, the more heat generated by the devices 206, the higher the temperature of the inert fluid 207 and any remaining air in the sealed recesses of the enclosure 101 can become without additional heat dissipation.

The enclosure 201 can include an integrated condenser to absorb heat from the inert fluid 207 and devices 206 disposed in the recesses. The enclosure 201 has walls that form a cavity to hold a cooling fluid 204 external from the recesses, which may be water or other liquid capable of absorbing heat through the walls of the enclosure 201. Since the walls of the enclosure 201 used to form the cavity also form the multiple recesses, the heat generated by the devices 206 can be transferred between the inert fluid 207 to the cooling fluid 204 in the cavity of the enclosure 201 through the walls shared by the recesses of the enclosure 201 and the cavity of the enclosure 201. In some embodiments, some of the walls in the cavity, for example, those walls corresponding to the recesses, can include heat dissipation structures, such as fins or other thermally conductive structures to increase a surface area of the walls. The walls on the interior of the recesses also may be chemically treated or otherwise altered to increase their surface area for heat dissipation.

In some embodiments, the enclosure 201 can include multiple ports, such as an inlet 202 and an outlet 203 for transport of a cooling fluid 204 to and from the cavity of the enclosure 201. The cavity of the enclosure 201 can receive the cooling fluid 204 via the inlet 202 and output the cooling fluid 204 via the outlet 203. As the cooling fluid 204 received from the inlet 202 passes through the cavity of the enclosure 201, the cooling fluid 204 can absorb heat from the inert fluid 207 through the walls shared with the recesses, such as heat generated by operation of devices 206. When the cooling fluid 204 is output from the cavity of the enclosure 201, the heat absorbed by the cooling fluid 204 from within the recesses of the enclosure 201 has been removed from the enclosure 201. An example flow of the cooling fluid 204 between the inlet 202 and the outlet is shown in FIG. 2C. Although not shown in FIGS. 2A-2C, the cavity of the enclosure 201 can include one or more flow control structures to direct a flow of the cooling fluid 204 through the cavity between the inlet 202 and the outlet 203. The enclosure 201 also may not include any ports, but instead dissipate heat from the cooling fluid 204 through the walls of the enclosure 201 to surrounding air, for example, with an air cooling system to control the flow and/or temperature of the air surrounding the enclosure 201.

The sealed liquid cooling system 200 can operate as a one phase system or a two phase system. When operating in a one phase system, the recesses in the sealed liquid cooling system 300 can be filled with the inert fluid 207. The sealed liquid cooling system 200 can prevent the inert fluid 207 from changing phases, for example, from a liquid phase to a gaseous phase through evaporation or boiling, through an adjustment of temperature or throughput of the cooling fluid 204 entering the enclosure. When operating in a two phase system, the recesses in the sealed liquid cooling system 200 can be partially filled with the inert fluid 207. The inert fluid 207 can be allowed to change phases, for example, from a liquid phase to a gaseous phase through evaporation or boiling. In some embodiments, the vaporized form of the inert fluid 207 can condense when contacting the walls of the recess, which transfers the heat from the vaporized form of the inert fluid 207 to the cooling fluid 204 through the walls of the recess.

By integrating condensing functionality with the enclosure 201, the sealed liquid cooling system 200 can more efficiently absorb heat from the inert fluid 207 held in the recesses, for example, due to the increased condensing surface area in contact with the portion of the walls forming recesses. This increased heat absorbing efficiency can allow the size of the recesses and the volume of the inert fluid 207 to be reduced, which can reduce cost by utilizing less inert fluid and overall product size. Although FIGS. 2A-2C show the walls of the enclosure 201 forming two recesses to hold the inert fluid 207 and the devices 206, any number of recesses may be formed. The recesses also may have varying dimensions or configurations within the sealed liquid cooling system 200.

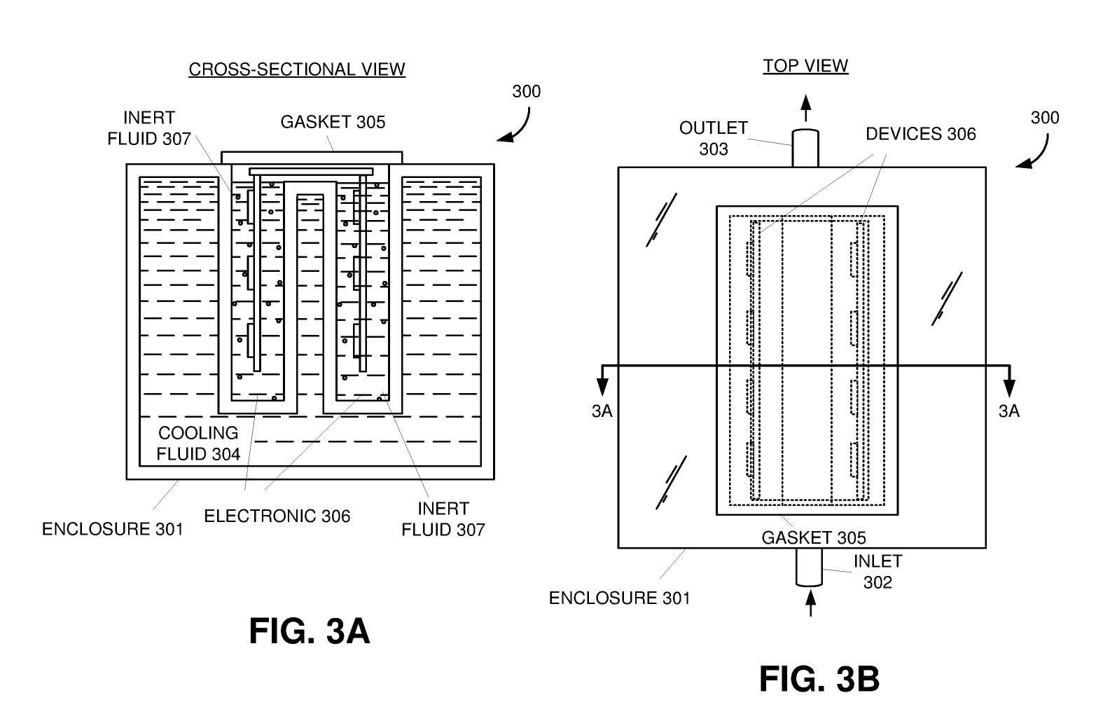

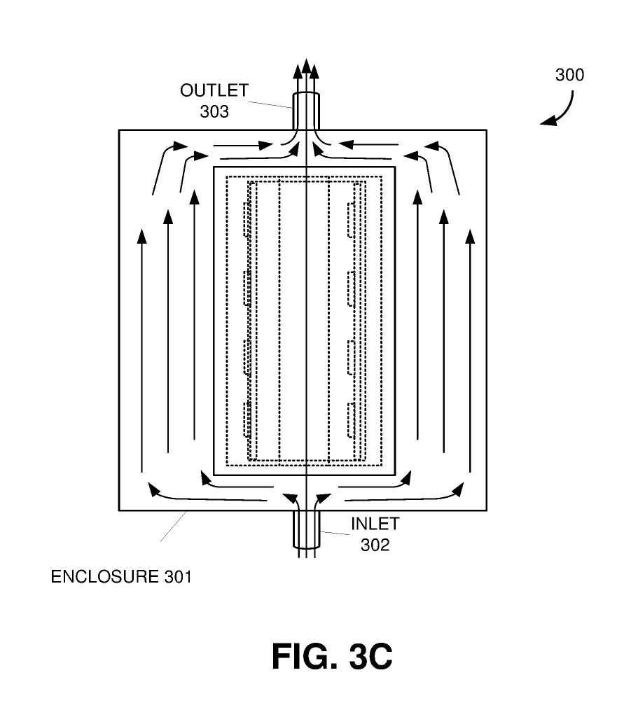

FIGS. 3A-3C illustrate another example of a sealed liquid cooling system 300 with integrated condenser. Referring to FIGS. 3A-3C, the sealed liquid cooling system 300 can include an enclosure 301 having a recess to hold inert fluid 307 and devices 306 submerged or at least partially submerged in the inert fluid 307. The inert fluid 307 can be an electrically inert fluid, such as Fluorinert® or the like, which can be an electrically insulating stable fluorocarbon-based fluid. The devices 306 may be electronic devices, such as integrated circuits, printed circuit boards, or the like, or the devices 306 may be mechanical devices, such as motors, industrial machinery, or the like. In some embodiments, the electronic devices may be a portion of an emulation system and/or a prototyping system having programmable logic devices mounted on printed circuit boards, for example, configured to implement functionality described in a logical design for an electronic system to be functionally verified.

As will be described below, the sealed liquid cooling system 300 can be similar to the sealed liquid cooling system 200 described above in FIGS. 2A-2C except with a shared recess to for the devices 306, a single gasket 305 to detachably couple to the enclosure 301 to seal the opening formed by the shared recess, and locations of multiple ports relative to the shared recess in the enclosure 301 can be different than the locations of the multiple ports relative to the shared recess in the enclosure 201. This difference in port locations relative to the shared recess can provide different flows of cooling fluid within the condenser integrated in the enclosures 201 and 301.

The shared recess in the enclosure 301 may include an opening, for example, allowing the addition and removal of the inert fluid 307 and/or the devices 306 from the shared recess in the enclosure 301. The shared recess can allow the devices 306 to be connected to each other. For example, when the devices 306 correspond to circuitry or devices mounted on printed circuit boards, the printed circuit boards can be couple via a backplane device also disposed in the shared recess. The sealed liquid cooling system 300 can include a gasket 305 configured to detachably couple to the enclosure to seal or close the opening, for example, encapsulating the inert fluid 307 and the devices 306 submerged or at least partially submerged in the shared recess of the enclosure 301.

The enclosure 301 can include an integrated condenser to absorb heat from the inert fluid 307 and the devices 306 disposed in the shared recess. The enclosure 301 has walls that form a cavity to hold a cooling fluid 304 external from the shared recess, which may be water or other liquid capable of absorbing heat through the walls. Since the walls of the enclosure 301 used to form the cavity also form the shared recess, the heat generated by the devices 306 can be transferred between the inert fluid 307 to the cooling fluid 304 in the cavity of the enclosure 301 through the walls shared by the recess of the enclosure 301 and the cavity of the enclosure 301. In some embodiments, some of the walls in the cavity, for example, those walls corresponding to the shared recess, can include heat dissipation structures, such as fins or other thermally conductive structures to increase a surface area of the walls. The walls on the interior of the shared recess also may be chemically treated or otherwise altered to increase their surface area for heat dissipation.

The multiple ports of the enclosure 301 can include an inlet 302 and an outlet 303 for transport of a cooling fluid 304 to and from the cavity of the enclosure 301. The cavity of the enclosure 301 can receive the cooling fluid 304 via the inlet 302 and output the cooling fluid 304 via the outlet 303. As the cooling fluid 304 received from the inlet 302 passes through the cavity of the enclosure 301, the cooling fluid 304 can absorb heat from the inert fluid 307 through the walls shared with the recess, such as heat generated by operation of devices 306. When the cooling fluid 304 is output from the cavity of the enclosure 301, the heat absorbed by the cooling fluid 304 from within the recess of the enclosure 301 has been removed from the enclosure 301. An example flow of the cooling fluid 304 between the inlet 302 and the outlet is shown in FIG. 3C. Although not shown in FIGS. 3A-3C, the cavity of the enclosure 301 can include one or more flow control structures to direct a flow of the cooling fluid 304 through the cavity between the inlet 302 and the outlet 303. The enclosure 301 also may not include any ports, but instead dissipate heat from the cooling fluid 304 through the walls of the enclosure 301 to surrounding air, for example, with an air cooling system to control the flow and/or temperature of the air surrounding the enclosure 301.

The sealed liquid cooling system 300 can operate as a one phase system or a two phase system. When operating in a one phase system, the shared recess in the sealed liquid cooling system 300 can be filled with the inert fluid 307. The sealed liquid cooling system 300 can prevent the inert fluid 307 from changing phases, for example, from a liquid phase to a gaseous phase through evaporation or boiling, through an adjustment of temperature or throughput of the cooling fluid 304 entering the enclosure 301. When operating in a two phase system, the shared recess in the sealed liquid cooling system 300 can be partially filled with the inert fluid 307. The sealed liquid cooling system 300 can allow the inert fluid 307 to change phases, for example, from a liquid phase to a gaseous phase through evaporation or boiling. In some embodiments, the vaporized form of the inert fluid 307 can condense when contacting the walls of the recess, which transfers the heat from the vaporized form of the inert fluid 307 to the cooling fluid 304 through the walls of the recess.

Although FIGS. 2A-2C and 3A-3C show an enclosure holding an inert fluid to cool devices, in some embodiments, the recess in the enclosure can hold one or more different fluids and/or heat or cool different devices or objects. For example, the enclosure can have walls forming a cavity to hold a first fluid and forming at least one recess to retain a second fluid different from the first fluid. The first fluid and the second fluid can exchange heat between them through the walls shared by the cavity and the recess. The enclosures in FIGS. 2A-2C and 3A-3C also show two implementations of the integrated condenser, for example, different configurations of the inlet and outlet of the cavities, respectively. In some embodiments, the enclosures can include one or more inlets and one or more outlets having various sizes or configurations and be located variously in the enclosure. Each of the different combinations of the port configuration and location, as well as a rate of cooling fluid flow through the inlet and outlet, can cause differing flow patterns and heat transfer capabilities through the walls of the recess in the enclosure.

### Conclusion

While the application describes specific examples of carrying out embodiments, those skilled in the art will appreciate that there are numerous variations and permutations of the above described systems and techniques that fall within the spirit and scope of the invention as set forth in the appended claims.

One of skill in the art will also recognize that the concepts taught herein can be tailored to a particular application in many other ways. In particular, those skilled in the art will recognize that the illustrated examples are but one of many alternative implementations that will become apparent upon reading this disclosure.

Although the specification may refer to “an”, “one”, “another”, or “some” example(s) in several locations, this does not necessarily mean that each such reference is to the same example(s), or that the feature only applies to a single example.

1. A system comprising:
a device configured to emit heat during operation; and
an enclosure having walls forming a cavity to hold a first fluid, wherein the walls form a recess to retain a second fluid external from the cavity, wherein the device is disposed in the recess and at least partially submerged in the second fluid, and wherein the second fluid absorbs the heat emitted by the electronic device and transfers the absorbed heat to the first fluid through the walls of the enclosure.

2. The system of claim 1, wherein the enclosure includes an inlet port configured to allow the first fluid into the cavity and an outlet port configured to output the first fluid from the cavity, and wherein a flow of the first fluid through the cavity from the inlet port to the outlet port dissipates the heat transferred from the electronic device to the first fluid.

3. The system of claim 1, wherein the walls of the enclosure that correspond to the cavity have thermally conductive structures, which increase a surface area of the walls for cooling the second fluid.

4. The system of claim 1, wherein the walls of the enclosure that correspond to the recess act as an integrated condenser for cooling the second fluid.

5. The system of claim 1, further comprising a gasket configured to couple to the walls of the enclosure covering an opening in the recess, which encapsulates the electronic device and the second fluid in the recess.

6. The system of claim 1, further comprising another device disposed in the recess and coupled to the device via a backplane.

7. The system of claim 1, wherein the devices includes an electronic device, and wherein the second fluid is an electrically inert fluid.

8. A device comprising:
a container configured to hold a first fluid; and
a recess formed by walls of the container, wherein the recess is configured to hold a second fluid different from the first fluid and to hold a device at least partially submerged in the second fluid, and wherein the second fluid transfers heat to the first fluid through the walls that form the recess.

9. The device of claim 8, further comprising:
an inlet port configured to allow the first fluid into the container; and
an outlet port configured to output the first fluid from the container, and wherein a flow of the first fluid through the container from the inlet port to the outlet port dissipates the heat transferred from the electronic device to the first fluid.

10. The device of claim 8, wherein the walls of the container that correspond to the recess act as an integrated condenser for cooling the second fluid.

11. The device of claim 8, further comprising a gasket configured to couple to the walls of the container covering an opening in the recess, which encapsulates the electronic device and the second fluid in the recess.

12. The system of claim 1, wherein the walls of the container have thermally conductive structures that increase a surface area of the walls contacting the first fluid.

13. The system of claim 8, wherein the recess is configured to hold another device coupled to the device via a backplane at least partially submerged in the second fluid.

14. The device of claim 8, wherein the device includes an electronic device, and wherein the second fluid is an electrically inert fluid.

15. A system comprising:
a device configured to emit heat during operation;
means for holding a first fluid and a second fluid separate from each other, wherein the device is submerged in the second fluid; and
means for condensing the second fluid having absorbed the heat emitted by the device, which transfers the heat to the first fluid.

16. The system of claim 15, wherein the means for condensing includes an inlet port configured to allow the first fluid into the means for holding, and includes an outlet port configured to output the first fluid from the means for holding, and wherein the means for condensing flows the first fluid through the means for holding from the inlet port to the outlet port, which dissipates the heat transferred from the device to the first fluid.

17. The system of claim 15, further comprising means for covering an opening in the means for holding, which encapsulates the device and the second fluid in the means for holding.

18. The system of claim 15, further comprising another device coupled to the device via a backplane and at least partially submerged in the second fluid.

19. The system of claim 15, wherein the device includes an electronic device, and wherein the second fluid is an electrically inert fluid.
